(19) United States
(12) Patent Application Publication
(10) Pub. No.: US 2026/0255687 A1
(43) Pub. Date: Aug. 27, 2026

(54) SEMICONDUCTOR DEVICE

(71) Applicant: FUJI ELECTRIC CO., LTD., Kawasaki-shi (JP)

(72) Inventor: Taichi KARINO, Matsumoto-city (JP)

(73) Assignee: FUJI ELECTRIC CO., LTD., Kawasaki-shi (JP)

(21) Appl. No.: 19/461,263

(22) Filed: Jan. 27, 2026

(30) Foreign Application Priority Data
Feb. 27, 2025 (JP) 2025-029892

(51) Int. Cl. H10D 89/60

(52) U.S. Cl. CPC H10D 89/611

(57) ABSTRACT

A semiconductor device, including: a terminal portion including a first terminal, a second terminal, and a third terminal; and a clamping circuit connected to the first terminal, the second terminal and the third terminal. The clamping circuit is configured to: in response to a first overvoltage externally applied between the first terminal and the third terminal, cause a first overcurrent to flow from the first terminal to the third terminal to thereby clamp the first overvoltage, and in response to a second overvoltage externally applied between the second terminal and the first terminal, cause a second overcurrent to flow from the second terminal to the first terminal to thereby clamp the second overvoltage.

### CROSS-REFERENCE TO RELATED APPLICATIONS

This application is based upon and claims the benefit of priority of the prior Japanese Patent Application No. 2025-029892, filed on Feb. 27, 2025, the entire contents of which are incorporated herein by reference.

### BACKGROUND OF THE INVENTION

### 1. Field of the Invention

The embodiment discussed herein relates to a semiconductor device.

### 2. Background of the Related Art

With an electronic apparatus including a semiconductor device or the like, when overvoltage such as electro-static discharge (ESD) occurs, a malfunction or a failure may occur. Therefore, measures are taken to satisfy the resistance of the overvoltage and protect the apparatus.

As a related technique, for example, a circuit has been proposed in which a plurality of diodes, the number of which is determined according to a potential difference between a first power supply voltage and a second power supply voltage, are provided between an output terminal of an open drain output circuit and an internal power supply line (Japanese Laid-open Patent Publication No. 2004-222119). In addition, there has been proposed a circuit which performs switching to turn on so as to short-circuit a terminal to a ground potential when overvoltage occurs, and clamps the overvoltage of the terminal to protect the terminal (Japanese Laid-open Patent Publication No. 2006-333595).

### SUMMARY OF THE INVENTION

According to an aspect of the present disclosure, there is provided a semiconductor device, including: a terminal portion including a first terminal, a second terminal, and a third terminal; and a clamping circuit connected to the first terminal, the second terminal and the third terminal, the clamping circuit being configured to: in response to a first overvoltage externally applied between the first terminal and the third terminal, cause a first overcurrent to flow from the first terminal to the third terminal to thereby clamp the first overvoltage, and in response to a second overvoltage externally applied between the second terminal and the first terminal, cause a second overcurrent to flow from the second terminal to the first terminal to thereby clamp the second overvoltage.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example of a semiconductor device;

FIG. 2 illustrates the structure of a semiconductor device taken as a reference example;

FIG. 3 is a view for describing an example of ESD protection if an ESD surge voltage is applied to a signal terminal with GND as reference;

FIG. 4 is a view for describing a state in which an ESD surge voltage is applied to a signal terminal with a power supply voltage as reference;

FIG. 5 illustrates an example of the structure of a section of an NPN transistor;

FIG. 6 illustrates an example of the structure of a semiconductor device according to the present embodiment;

FIG. 7 is a view for describing an example of first ESD protection operation; and

FIG. 8 is a view for describing an example of second ESD protection operation.

### DETAILED DESCRIPTION OF THE INVENTION

An embodiment will now be described with reference to the drawings. In this specification and the appended drawings, components that have substantially the same structure are marked with the same reference numerals, and repeated description of these components may be omitted.

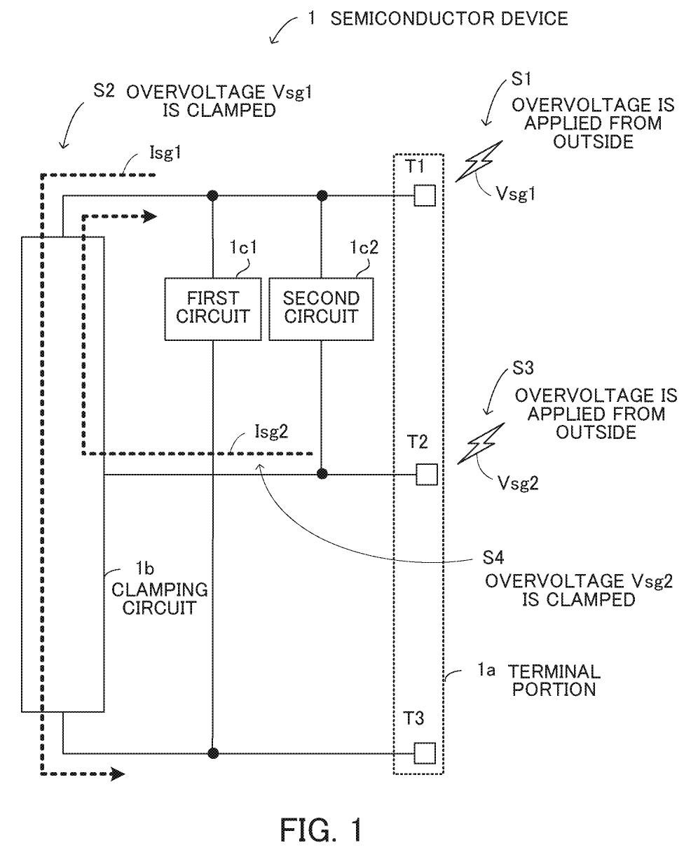

FIG. 1 is a view for describing an example of a semiconductor device. A semiconductor device 1 includes a terminal portion 1a and a clamping circuit 1b. The terminal portion 1a includes a terminal T1 (first terminal), a terminal T2 (second terminal), and a terminal T3 (third terminal). Furthermore, a first circuit 1c1 is connected to the terminals T1 and T3 and a second circuit 1c2 is connected to the terminals T1 and T2.

[Step S1] Overvoltage Vsg1 (first overvoltage) is applied from the outside between the terminal T1 and the terminal T3. The overvoltage Vsg1 is, for example, an ESD surge voltage generated if a human body touches a metal terminal or the like.

[Step S2] If the overvoltage Vsg1 is applied, then the clamping circuit 1b causes an overcurrent Isg1 (first overcurrent) associated with the application of the overvoltage Vsg1 to flow in a direction from the terminal T1 to the terminal T3 to clamp the overvoltage Vsg1. By doing so, the first circuit 1c1 is protected against the overvoltage Vsg1.

[Step S3] Overvoltage Vsg2 (second overvoltage) is applied from the outside between the terminal T2 and the terminal T1. The overvoltage Vsg2 is, for example, an ESD surge voltage generated if a human body touches a metal terminal or the like.

[Step S4] If the overvoltage Vsg2 is applied, then the clamping circuit 1b causes an overcurrent Isg2 (second overcurrent) associated with the application of the overvoltage Vsg2 to flow in a direction from the terminal T2 to the terminal T1 to clamp the overvoltage Vsg2. By doing so, the second circuit 1c2 is protected against the overvoltage Vsg2.

As described above, with the semiconductor device 1, the clamping circuit 1b controls overvoltage protection in response to both the overvoltage Vsg1 applied between the terminal T1 and the terminal T3 and the overvoltage Vsg2 applied between the terminal T2 and the terminal T1.

Accordingly, for example, if the terminal T1 is a power supply terminal, the terminal T2 is a signal terminal, and the terminal T3 is a ground terminal, then it is possible to increase overvoltage resistance not only against overvoltage applied to the power supply terminal with GND of the ground terminal as reference but also against overvoltage applied to the signal terminal with VCC of the power supply terminal as reference.

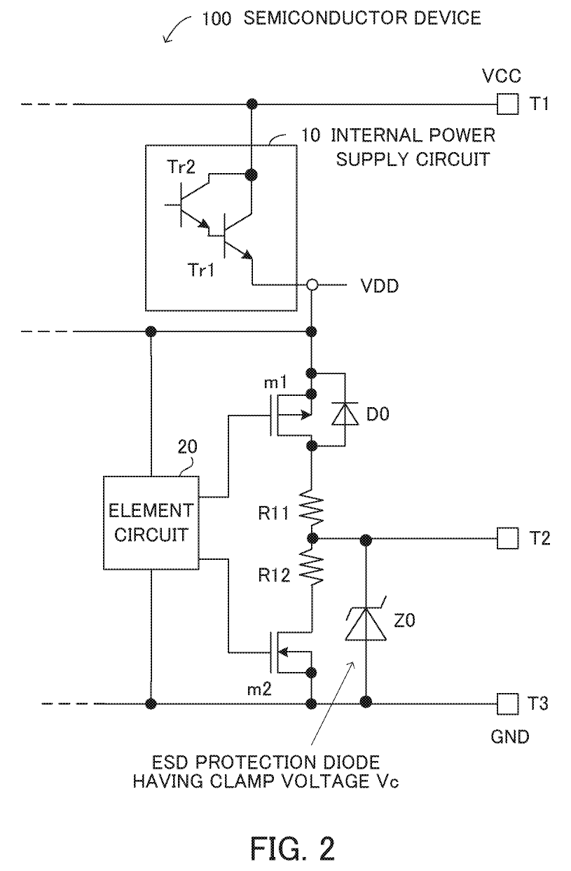

Overvoltage protection of a semiconductor device taken as a reference example will now be described with reference to FIGS. 2 to 5. Hereinafter, it is assumed that ESD occurs at a terminal, and an overvoltage is referred to as an ESD surge voltage and an overcurrent is referred to as an ESD surge current. Furthermore, a terminal T1 is a power supply terminal T1 to which a power supply voltage is supplied, a terminal T2 is a signal terminal T2 through which a signal is communicated, and a terminal T3 is a ground terminal T3 connected to GND.

FIG. 2 illustrates the structure of a semiconductor device taken as a reference example. A semiconductor device 100 taken as a reference example includes the power supply terminal T1, the signal terminal T2, and the ground terminal T3. Furthermore, the semiconductor device 100 includes an internal power supply circuit 10, an element circuit 20, a PMOS transistor m1 that is a P-type metal-oxide-semiconductor (MOS) transistor, an NMOS transistor m2 that is an N-type MOS transistor, resistors R11 and R12, and a Zener diode Z0.

The internal power supply circuit 10 includes transistors Tr1 and Tr2. NPN transistors are used as the transistors Tr1 and Tr2. Collectors of the transistors Tr1 and Tr2 are connected to each other and an emitter of the transistor Tr2 is connected to a base of the transistor Tr1. Accordingly, the transistors Tr1 and Tr2 are Darlington connected. The Darlington-connected transistors Tr1 and Tr2 operate as one transistor having a high current amplification factor.

The collectors of the transistors Tr1 and Tr2 are connected to the power supply terminal T1. In addition, when a predetermined base current is input to a base of the transistor Tr2, the transistors Tr1 and Tr2 are turned on and an internal power supply voltage VDD is output from an emitter of the transistor Tr1.

A power supply end of the element circuit 20 is connected to the emitter of the transistor Tr1 and the internal power supply voltage VDD generated by the internal power supply circuit 10 is supplied to the element circuit 20. A ground end of the element circuit 20 is connected to the ground terminal T3.

In addition, the emitter of the transistor Tr1 is connected to a source of the PMOS transistor m1, a back gate of the PMOS transistor m1, and a cathode of a body diode D0 connected in inverse parallel with the PMOS transistor m1.

A drain of the PMOS transistor m1 is connected to one end of the resistor R11 and an anode of the body diode D0. The other end of the resistor R11 is connected to one end of the resistor R12, a cathode of the Zener diode Z0, and the signal terminal T2.

The other end of the resistor R12 is connected to a drain of the NMOS transistor m2. A source of the NMOS transistor m2 is connected to a back gate of the NMOS transistor m2, an anode of the Zener diode Z0, and the ground terminal T3. A gate of the PMOS transistor m1 is connected to a first output end of the element circuit 20 and a gate of the NMOS transistor m2 is connected to a second output end of the element circuit 20.

The element circuit 20 includes a circuit that detects an operation state of the semiconductor device 100. The element circuit 20 outputs a first detection signal indicative of a first operation state from the first output end, exercises switching control of the PMOS transistor m1, and outputs a voltage level indicative of the first operation state from the signal terminal T2. Furthermore, the element circuit 20 outputs a second detection signal indicative of a second operation state from the second output end, exercises switching control of the NMOS transistor m2, and outputs a voltage level indicative of the second operation state from the signal terminal T2.

On the other hand, if an ESD surge voltage is applied to the signal terminal T2 with GND as reference, the Zener diode Z0 functions as an ESD protection diode that performs ESD protection by ensuring ESD resistance between the signal terminal T2 and the ground terminal T3. It is assumed that a clamp voltage of the Zener diode Z0 is a clamp voltage Vc.

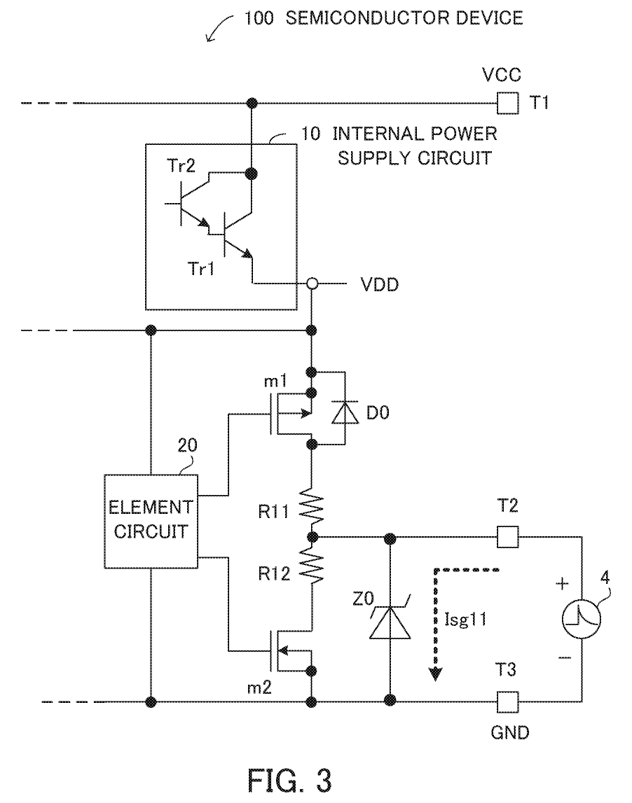

FIG. 3 is a view for describing an example of ESD protection if an ESD surge voltage is applied to a signal terminal with GND as reference. When the semiconductor device 100 performs normal operation, the Zener diode Z0 is in an off state.

On the other hand, it is assumed that an ESD surge voltage equal to or higher than the clamp voltage Vc is applied to the signal terminal T2 with GND as reference (FIG. 3 illustrates this state by connecting a positive electrode side of an ESD generation source 4 to the signal terminal T2 and connecting a negative electrode side of the ESD generation source 4 to the ground terminal T3).

In this case, the Zener diode Z0 breaks down and goes into an on state, and an ESD surge current Isg11 flows to a GND side of the ground terminal T3 to clamp the ESD surge voltage. This prevents the ESD surge voltage from being applied to a circuit (NMOS transistor m2 in the example of FIG. 3) connected to the signal terminal T2 and the ground terminal T3. By doing so, the circuit is protected against the ESD surge voltage.

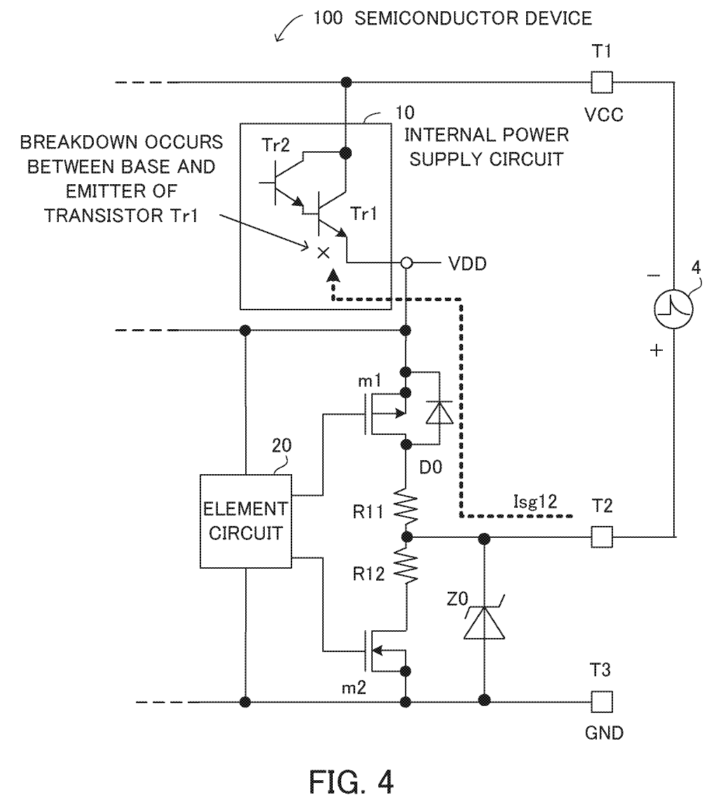

FIG. 4 is a view for describing a state in which an ESD surge voltage is applied to a signal terminal with a power supply voltage as reference. It is assumed that an ESD surge voltage is applied to the signal terminal T2 with VCC as reference (FIG. 4 illustrates this state by connecting a positive electrode side of an ESD generation source 4 to the signal terminal T2 and connecting a negative electrode side of the ESD generation source 4 to the power supply terminal T1).

In this case, an ESD surge current Isg12 generated as a result of the ESD surge voltage flows from the anode of the body diode D0 toward the emitter of the transistor Tr1 through the cathode thereof. When the ESD surge current Isg12 flows to the emitter of the transistor Tr1, a breakdown may occur between the base and the emitter of the transistor Tr1.

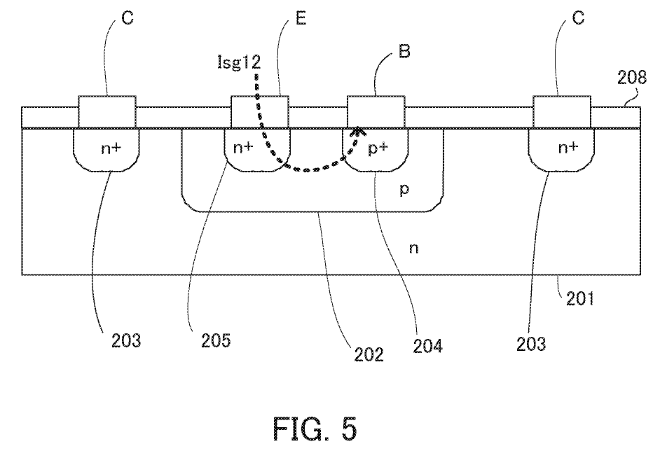

FIG. 5 illustrates an example of the structure of a section of an NPN transistor. In an NPN-type transistor, a P-type base layer 202 is formed in a surface layer of an N-type substrate 201 and a P+ -type base layer 204 and an N+ -type emitter layer 205 are formed in a surface layer of the P-type base layer 202. Furthermore, an N+ -type collector layer 203 is formed in the surface layer of the N-type substrate 201. An oxide film 208 is formed on the surface of the N-type substrate 201. An emitter electrode E is formed on the surface of the N+ -type emitter layer 205, a base electrode B is formed on the surface of the P+ -type base layer 204, and a collector electrode C is formed on the surface of the N+ -type collector layer 203.

With the above structure of the NPN-type transistor, when the ESD surge current Isg12 flows toward the emitter electrode E of the transistor Tr1, a pulse of abnormal energy of ESD intrudes from the emitter electrode E of the transistor Tr1 toward the base electrode B via the N+ -type emitter layer 205, the P-type base layer 202, and the P+ -type base layer 204. This may cause deterioration or a breakdown between the base and the emitter of the transistor Tr1.

With the conventional ESD measures, ESD resistance is guaranteed only with reference to GND. Therefore, with external terminals of a semiconductor device in which ESD may occur, ESD resistance is satisfied by incorporating a protection element in a ground terminal or increasing the resistance of the semiconductor device itself (such as increasing wafer size).

For example, with the semiconductor device 100 taken as a reference example, as illustrated in FIG. 3, the Zener diode Z0 is inserted between the signal terminal T2 and the ground terminal T3. As a result, if an ESD surge voltage is applied to the signal terminal T2 with GND as reference, a circuit arranged between the signal terminal T2 and the ground terminal T3 is protected against the ESD surge voltage.

The semiconductor device 100 has a structure for performing ESD protection with GND as reference, but the semiconductor device 100 does not have a structure for performing ESD protection with VCC as reference. Therefore, if an ESD surge voltage is applied to the signal terminal T2 with VCC as reference, it is difficult to protect a circuit (transistor Tr1 in the example of FIG. 4) arranged between the power supply terminal T1 and the signal terminal T2 against the ESD surge voltage.

The present embodiment has been made in view of the above point, and enables not only ESD protection in which ESD resistance between a signal terminal and a ground terminal is increased but also ESD protection in which ESD resistance between the signal terminal and a power supply terminal is increased.

A semiconductor device according to the present embodiment will now be described in detail. A case where the present embodiment is applied to a low voltage IC (LVIC) of an intelligent power module (IPM) will be described as an example.

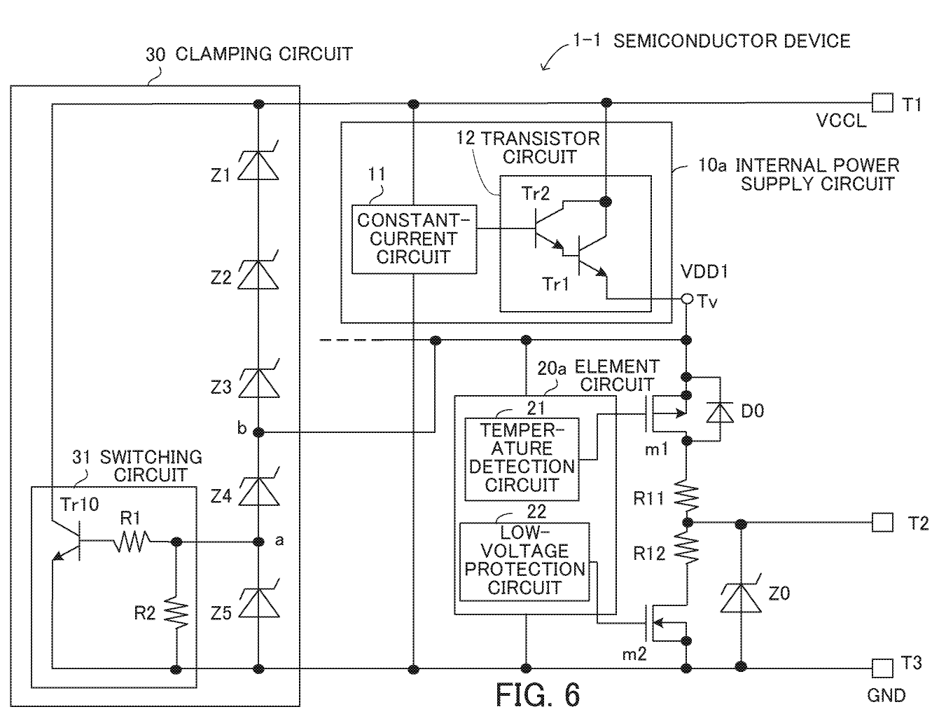

FIG. 6 illustrates an example of the structure of a semiconductor device according to the present embodiment. A semiconductor device 1-1 includes a power supply terminal T1 to which a power supply voltage VCCL is applied, a signal terminal T2 from which a signal indicative of a device state is output, and a ground terminal T3 connected to GND. The ground terminal T3 corresponds to a terminal COM connected to GND common to an upper arm control circuit and a lower arm control circuit of the IPM.

The semiconductor device 1-1 includes an internal power supply circuit 10a, an element circuit 20a, a PMOS transistor m1, an NMOS transistor m2, resistors R11 and R12, a Zener diode Z0, and a clamping circuit 30.

The internal power supply circuit 10a includes a constant-current circuit 11 and a transistor circuit 12 and the transistor circuit 12 includes the above transistors Tr1 and Tr2. As illustrated in FIG. 2, the transistors Tr1 and Tr2 are Darlington connected. An output end of the constant-current circuit 11 is connected to a base of the transistor Tr2.

When a constant current output from the output end of the constant-current circuit 11 is input to the base of the transistor Tr2, the transistors Tr1 and Tr2 are turned on, and an internal power supply voltage VDD1 is output from an emitter of the transistor Tr1.

An internal power supply terminal Tv is a terminal which is connected to the emitter of the transistor Tr1 and to which the internal power supply voltage VDD1 is applied (the internal power supply terminal Tv and wiring connected to the internal power supply terminal Tv correspond to a predetermined wiring portion which is electrically connected to the signal terminal T2 when an ESD surge voltage Vsg2 is generated).

The element circuit 20a includes a temperature detection circuit 21 and a low-voltage protection circuit 22. The temperature detection circuit 21 and the low-voltage protection circuit 22 are driven by the internal power supply voltage VDD1. The temperature detection circuit 21 detects temperature at the time of driving a switching element (not illustrated) included in the semiconductor device 1-1 and outputs a temperature detection signal having a voltage corresponding to the temperature to a gate of the PMOS transistor m1. The PMOS transistor m1 supplies a current corresponding to the voltage of the temperature detection signal output from the temperature detection circuit 21, and outputs a voltage corresponding to the temperature from the signal terminal T2.

The low-voltage protection circuit 22 detects a voltage level of the power supply voltage VCCL or the internal power supply voltage VDD1, and outputs a low voltage detection signal at an H level to a gate of the NMOS transistor m2 if the power supply voltage VCCL or the internal power supply voltage VDD1 becomes equal to or lower than a predetermined voltage.

The NMOS transistor m2 is turned on if the low voltage detection signal at the H level is output from the low-voltage protection circuit 22, and blocks an output voltage from the signal terminal T2 (signal terminal T2 becomes an L level in a low voltage abnormal state).

The clamping circuit 30 has the function of the clamping circuit 1b illustrated in FIG. 1, and includes Zener diodes Z1 to Z5 and a switching circuit 31. The switching circuit 31 includes a transistor Tr10, a resistor R1, and a resistor R2. An NPN transistor is used as the transistor Tr10.

The transistor Tr10 is turned on if an ESD surge voltage (first overvoltage) is applied to the power supply terminal T1 with GND as reference. The Zener diodes Z1 to Z5 in the series stage are connected in parallel with the transistor Tr10. A plurality of Zener diodes may be connected in series in n stages. In the example of FIG. 6, the number of stages is five. n is a natural number (usually, n is a natural number greater than or equal to 3). Furthermore, the resistor R1 is a base resistor of the transistor Tr10 and the resistor R2 is a pull-down resistor that pulls down the potential of a base of the transistor Tr10 to a ground voltage.

The components of the clamping circuit 30 are connected in the following way. A collector (high potential terminal) of the transistor Tr10 is connected to a cathode of the Zener diode Z1 (first Zener diode) and the power supply terminal T1. The base (control terminal) of the transistor Tr10 is electrically connected to a cathode of the Zener diode Z5. The base of the transistor Tr10 is connected to one end of the resistor R1 and the other end of the resistor R1 is connected to one end of the resistor R2, an anode of the Zener diode Z4, and a cathode of the Zener diode Z5. An emitter (low potential terminal) of the transistor Tr10 is connected to the other end of the resistor R2, an anode of the Zener diode Z5 (n-th Zener diode), and the ground terminal T3.

An anode of the Zener diode Z1 is connected to a cathode of the Zener diode Z2 and an anode of the Zener diode Z2 is connected to a cathode of the Zener diode Z3. An anode of the Zener diode Z3 is connected to a cathode of the Zener diode Z4, the internal power supply terminal Tv, the emitter of the transistor Tr1, a power supply end of the element circuit 20a, a source of the PMOS transistor m1, and a cathode of a body diode D0.

A predetermined connection position a (first connection position) of the series connection of a plurality of Zener diodes is pulled down to the ground terminal T3 at the time of normal operation of the device. The predetermined connection position a has a first potential (potential based on GND of the ground terminal T3) determined by a Zener voltage (breakdown voltage) in a predetermined number of stages of Zener diodes and a resistance value of the resistor R2 at the time of applying first overvoltage.

In the example of FIG. 6, a Zener voltage in the predetermined number of stages of Zener diodes at the time of applying the first overvoltage corresponds to the Zener voltage of the Zener diode Z5. At the time of applying the first overvoltage, the first potential determined by the Zener voltage of the Zener diode Z5 and the resistance value of the resistor R2 is a potential at the connection position a. At this time, the first potential is set to the Zener voltage of the Zener diode Z5 by adjusting the resistance value of the resistor R2. For example, the resistance value of the resistor R2 is 100 kΩ.

Furthermore, it is assumed that at the time of normal operation of the device, a potential at the internal power supply terminal Tv is a second potential with GND of the ground terminal T3 as reference. At the time of normal operation of the device, a position where a potential is higher than the second potential is set as a connection position b (second connection position) and the internal power supply terminal Tv is set to be connected to the connection position b. Therefore, if an ESD surge voltage (second overvoltage) is generated at the signal terminal T2 with the power supply terminal T1 as reference, then the signal terminal T2 is connected to the connection position b via the body diode D0 and an internal power supply wiring portion.

For example, it is assumed that at the time of normal operation of the device, the second potential at the connection position b is 7.4 V and the second potential at the internal power supply terminal Tv is 5 V with GND of the ground terminal T3 as reference. In this case, the potential at the connection position b is higher than that at the internal power supply terminal Tv. Therefore, if the internal power supply terminal Tv is connected to the connection position b, the potential at the internal power supply terminal Tv is maintained at 5 V at the time of normal operation of the device.

On the other hand, if the connection position b is set between the anode of the Zener diode Z4 and the cathode of the Zener diode Z5 (which is the same as the connection position a), then a potential of 5 V at the internal power supply terminal Tv is not maintained because the connection position a is pulled down to the ground terminal T3 at the time of normal operation of the device.

Therefore, a position other than the connection position a is defined as the connection position b. That is to say, if one of a position between the anode of the Zener diode Z1 and the cathode of the Zener diode Z2, a position between the anode of the Zener diode Z2 and the cathode of the Zener diode Z3, and a position between the anode of the Zener diode Z3 and the cathode of the Zener diode Z4 is set as the connection position b, then a potential of 5 V at the internal power supply terminal Tv is maintained at the time of normal operation of the device. In addition, the connection position b is determined according to ESD resistance to be guaranteed between the power supply terminal T1 and the signal terminal T2. In FIG. 6, as an example, the connection position b is set between the anode of the Zener diode Z3 and the cathode of the Zener diode Z4.

As has been described, the Zener diodes Z1 to Z5 included in the clamping circuit 1b are conducted in the reverse direction to Zener diodes of n stages if the first overvoltage is generated, and the Zener diodes Z1 to Z5 are conducted in the forward direction to Zener diodes of m stages (m is a natural number smaller than n) if the second overvoltage is generated.

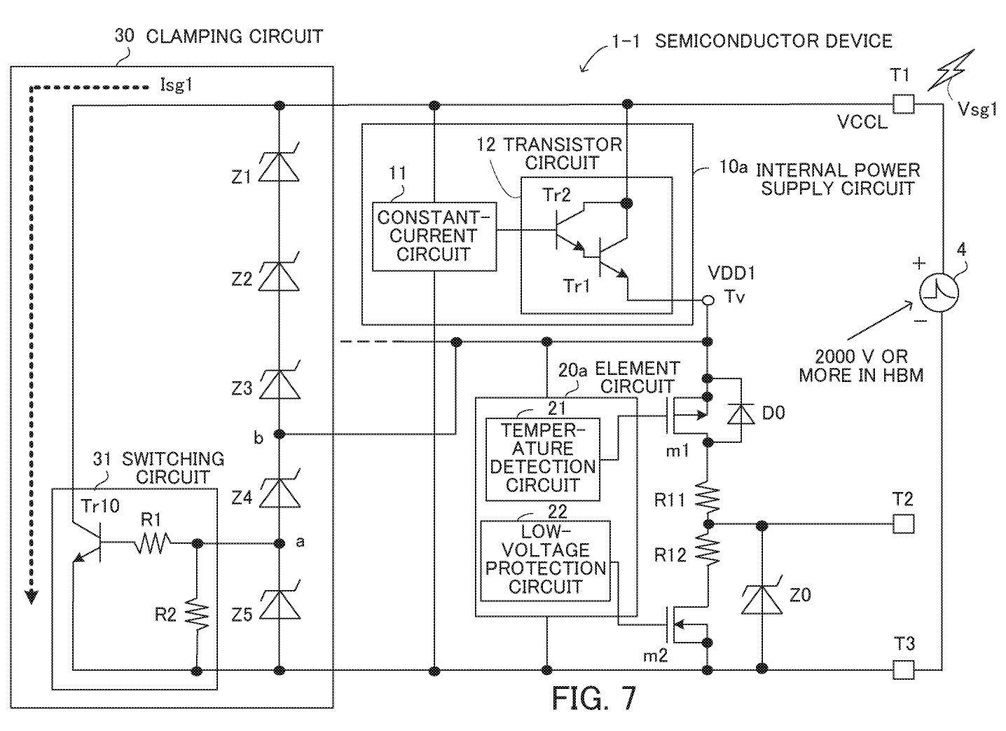

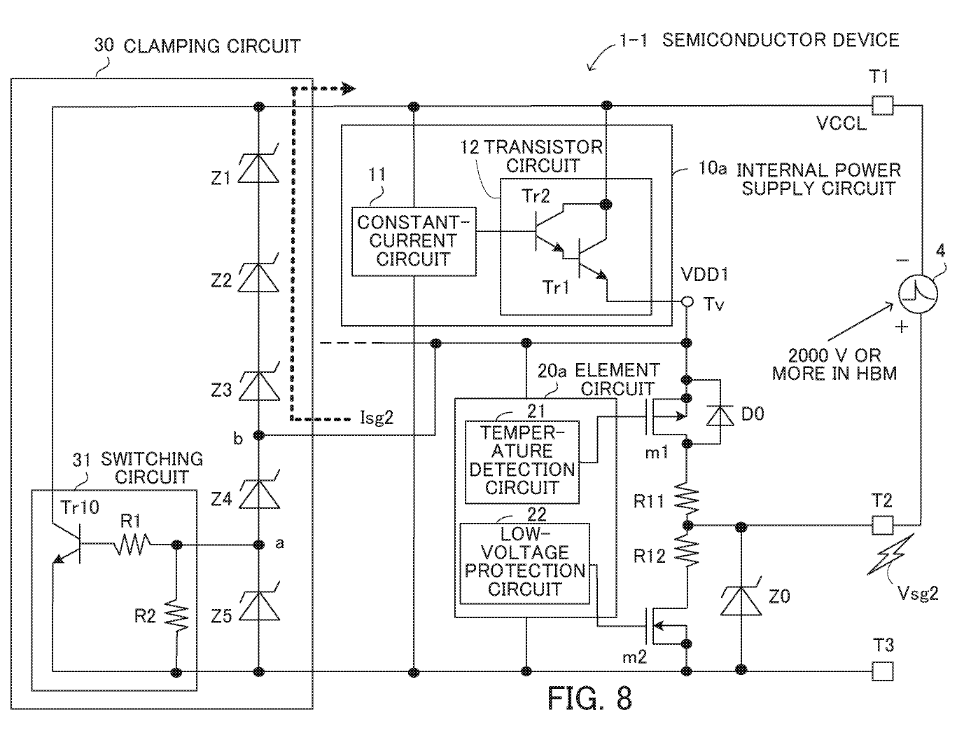

ESD protection operation in the clamping circuit 30 included in the semiconductor device 1-1 will now be described with reference to FIGS. 7 and 8. It is specified that ESD withstand voltage is guaranteed to be 2000 V or more in human body model (HBM), and the clamping circuit 30 performs ESD protection satisfying this specification.

The clamping circuit 30 has both functions of first ESD protection operation performed if an ESD surge voltage Vsg1 is generated at the power supply terminal T1 with GND as reference and second ESD protection operation performed if an ESD surge voltage Vsg2 is generated at the signal terminal T2 with a power supply voltage as reference.

FIG. 7 is a view for describing an example of the first ESD protection operation. If the ESD surge voltage Vsg1 is generated at the power supply terminal T1 with GND as reference (FIG. 7 illustrates this state by connecting a positive electrode side of an ESD generation source 4 to the power supply terminal T1 and connecting a negative electrode side of the ESD generation source 4 to the ground terminal T3), then the clamping circuit 30 performs first ESD protection for a circuit arranged between the ground terminal T3 and the power supply terminal T1.

With the first ESD protection operation, if the ESD surge voltage Vsg1 is generated at the power supply terminal T1 with GND of the ground terminal T3 as reference, the Zener diodes Z1 to Z5 break down and conduct in the reverse direction.

At this time, a voltage (at an on level) applied to a connection point of the anode of the Zener diode Z4 and the cathode of the Zener diode Z5 is applied to one end of the resistor R1 serving as a base resistor and a base current flows through the transistor Tr10 to turn on the transistor Tr10.

When the transistor Tr10 is turned on, a collector current corresponding to an ESD surge current Isg1 flows from the collector to the emitter. Furthermore, it is assumed that the DC current amplification factor of the transistor Tr10 is hfe, the collector current is several tens to several hundreds times the base current according to the DC current amplification factor hfe. Therefore, if the ESD surge voltage Vsg1 is generated at the power supply terminal T1, the transistor Tr10 is turned on. As a result, the ESD surge current Isg1 associated with the generation of the ESD surge voltage Vsg1 is drawn from the power supply terminal T1.

By adopting the above structure, the ESD surge voltage Vsg1 applied to the power supply terminal T1 with GND as reference is clamped at a predetermined voltage. This clamping protects a circuit connected to the power supply terminal T1 and the ground terminal T3 against the ESD surge voltage Vsg1. In the example of FIG. 7, the constant-current circuit 11 (corresponding to the first circuit 1c1 in FIG. 1) connected to the power supply terminal T1 and the ground terminal T3 is protected against the ESD surge voltage Vsg1.

The transistor Tr10 functions as a switch that releases the ESD surge voltage Vsg1 applied to the power supply terminal T1 to GND. However, until the Zener diodes Z1 to Z5 exceed a clamp voltage, an off state is held by the resistor R2 having a predetermined resistance value. Therefore, a current does not flow from the power supply terminal T1 to GND through the transistor Tr10. In addition, the resistor R2 also has the function of extracting charges remaining in the base of the transistor Tr10, for example, because the charges remaining in the base of the transistor Tr10 immediately after the device is restarted cause a malfunction of the transistor Tr10.

FIG. 8 is a view for describing an example of the second ESD protection operation. If the ESD surge voltage Vsg2 is generated at the signal terminal T2 with the power supply voltage VCCL as reference (FIG. 8 illustrates this state by connecting the positive electrode side of the ESD generation source 4 is connected to the signal terminal T2 and connecting the negative electrode side of the ESD generation source 4 to the power supply terminal T1), then the clamping circuit 30 performs the second ESD protection for a circuit arranged between the power supply terminal T1 and the signal terminal T2.

As the second ESD protection operation, if the ESD surge voltage Vsg2 is generated at the signal terminal T2 with the power supply voltage VCCL of the power supply terminal T1 as reference, then an ESD surge current Isg2 flowing from the signal terminal T2 via the body diode D0 flows in the forward direction through the Zener diodes Z3, Z2, and Z1 located between the power supply terminal T1 and the connection position b. That is to say, the ESD surge current Isg2 associated with the generation of the ESD surge voltage Vsg2 flows from the signal terminal T2 toward the power supply terminal T1.

With adopting this structure, the ESD surge voltage Vsg2 applied to the signal terminal T2 with the voltage VCCL as reference is clamped at a predetermined voltage. This clamping protects a circuit connected to the power supply terminal T1 and the signal terminal T2 against the ESD surge voltage Vsg2. In the example of FIG. 8, the transistor Tr1 (corresponding to the second circuit 1c2 in FIG. 1) connected to the power supply terminal T1 and the signal terminal T2 is protected against the ESD surge voltage Vsg2.

According to one aspect, it is possible to increase overvoltage resistance between a power supply terminal and a ground terminal and overvoltage resistance between a predetermined terminal and the power supply terminal.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a terminal portion including a first terminal, a second terminal, and a third terminal; and
a clamping circuit connected to the first terminal, the second terminal and the third terminal, the clamping circuit being configured to:
in response to a first overvoltage externally applied between the first terminal and the third terminal, cause a first overcurrent to flow from the first terminal to the third terminal to thereby clamp the first overvoltage, and
in response to a second overvoltage externally applied between the second terminal and the first terminal, cause a second overcurrent to flow from the second terminal to the first terminal to thereby clamp the second overvoltage.

2. The semiconductor device according to claim 1, further comprising:
a first circuit connected to the first terminal and the third terminal; and
a second circuit connected to the first terminal and the second terminal,
wherein the clamping circuit is further configured to:
clamp the first overvoltage by short-circuiting a potential of the first terminal to a potential of the third terminal, to thereby protect the first circuit against the first overvoltage; and
clamp the second overvoltage by short-circuiting a potential of the second terminal to a potential of the first terminal, to thereby protect the second circuit against the second overvoltage.

3. The semiconductor device according to claim 2, wherein the clamping circuit includes a plurality of Zener diodes connected in series in n stages, n being a natural number.

4. The semiconductor device according to claim 3, further comprising a wiring portion, which
is configured to be electrically connected to the second terminal when the second overvoltage is applied,
has a second potential at a time of a normal operation of the semiconductor device, and
is connected to a connection position, which is a position between adjacent two of the plurality of Zener diodes connected in series, and at which a potential is higher than the second potential.

5. The semiconductor device according to claim 4, wherein
the plurality of Zener diodes includes at least one Zener diode located between the first terminal and the connection position, and
the second overvoltage is clamped when the second overcurrent flows in a forward direction through the at least one Zener diode.

6. The semiconductor device according to claim 5, wherein the first overvoltage is clamped when the first overcurrent flows in a reverse direction through the plurality of Zener diodes connected in series.

7. The semiconductor device according to claim 3, wherein
the plurality of Zener diodes connected in series in the n stages includes:
a first Zener diode at a first stage, and
an n-th Zener diode at an n-th stage; and
the semiconductor device further includes a switching circuit that is connected in parallel with the plurality of Zener diodes and includes a transistor, the transistor having:
a high potential terminal connected to a cathode of the first Zener diode and the first terminal;
a low potential terminal connected to an anode of the n-th Zener diode and the third terminal; and
a control terminal connected to the third terminal via a resistor.

8. The semiconductor device according to claim 7, wherein the transistor draws the first overcurrent from the first terminal by switching at an on level determined when the plurality of Zener diodes conduct in a reverse direction by the first overvoltage.

9. The semiconductor device according to claim 8, wherein the control terminal of the transistor is electrically connected to a cathode of the n-th Zener diode.

10. The semiconductor device according to claim 7, further comprising a wiring portion, which
is electrically connected to the second terminal when the second overvoltage is applied,
has a second potential at a time of a normal operation of the semiconductor device, and
is connected to a connection position, which is a position between adjacent two of the plurality of Zener diodes connected in series, and at which a potential is higher than the second potential.

11. The semiconductor device according to claim 10, wherein
the plurality of Zener diodes includes at least one Zener diode located between the first terminal and the connection position, and
the second overvoltage is clamped when the second overcurrent flows in a forward direction through the at least one Zener diode.

12. The semiconductor device according to claim 11, wherein the first overvoltage is clamped when the first overcurrent flows in a reverse direction through the plurality of Zener diodes connected in series.

13. The semiconductor device according to claim 1, wherein
the first terminal is a power supply terminal,
the second terminal is a signal terminal, and
the third terminal is a ground terminal.
